(19) United States
(12) Patent Application Publication
(10) Pub. No.: US 2010/0332942 A1
(43) Pub. Date: Dec. 30, 2010

(54) Memory controller for NAND memory using forward error correction

(75) Inventors: Martinus Cornelis Wezelenburg, Kessel-Lo (Leuven) (BE); Thomas Kelshaw Conway, Cambridge (GB); Dominic Hugo Symes, Cambridge (GB)

Correspondence Address: NIXON & VANDERHYE P.C., 901 N. Glebe Road, 11th Floor, Arlington, VA, 22203-1808, US

(73) Assignee: ARM Limited, Cambridge (GB)

(21) Appl. No.: 12/232,106

(22) Filed: Sep. 10, 2008

(51) Int. Cl. G11C 29/04; G06F 11/07

(52) U.S. Cl. 714/763; 714/E11.022

(57) ABSTRACT

A memory controller 4 for a NAND memory array 2 includes error detecting circuitry having input circuitry 6, fast zero-error detecting circuitry 10, fast-path error correcting circuitry 16, 24, slow-path error correcting circuitry 18, 22 and fast-bad-block detecting circuitry 28.

### BACKGROUND OF THE INVENTION

1. Field of the Invention

This invention relates to the field of memory controllers for reading NAND memory. More particularly, this invention relates to memory controllers for reading NAND memory that employ forward error correction.

2. Description of the Prior Art

It is known to utilise NAND memory to provide high density, low cost storage in many recent data processing systems. A problem with such memory is that symbol errors (e.g. bit errors) in the data read from the memory are relatively common, in particular for Multi-Level Cell (MLC) NAND memory, and tend to increase with time as the memory ages.

In order to deal with this type of symbol error it is known to provide techniques such as forward error correction (FEC) that add redundant data to data stored so as to enable symbol errors to be detected and corrected. While such forward error correction is effective in coping with symbol errors, it is computationally intensive requiring significant circuit resource and introducing significant latency into the data read paths.

### SUMMARY OF THE INVENTION

Viewed from one aspect the present invention provides a memory controller for a NAND memory array, said memory controller comprising error detecting circuitry having:

input circuitry for accepting a block of symbols as a stream of symbols at a rate of A symbols per cycle;

fast zero-error detecting circuitry responsive to said block of symbols read from said NAND memory to detect that said block of symbols has values corresponding to zero symbol errors being present;

fast-path error correcting circuitry providing M fast computational paths, an i^{th} fast computational path of said M fast computational paths providing correction for any permutation of i symbol-errors within said block of symbols, where M is an integer value greater than zero and less than a maximum number of symbol-errors E to be corrected and i varies within a range 0<i≦M, said fast-path error correcting circuitry generating a stream of corrected symbols at rate of B symbols per cycle;

slow-path error correcting circuitry providing correction for any permutation of Y symbol-errors within said block of symbol symbols, where Y is an integer value within a range greater than M and less than E, said slow-path error generating a stream of corrected symbols at rate of C symbols per cycle, where C is less than B; and

fast bad-block detecting circuitry adapted to detect that said block of symbols is a bad-block having greater than E symbol-errors and cannot be corrected by said error correcting circuitry, said fast bad-block detecting circuitry being formed to guarantee bad-block detection up when said block of symbols contains T or less symbol-errors, where T is greater than E.

The present technique provides error detecting circuitry with a form matched to the error characteristics of a NAND memory so as to provide an advantageously efficient overall system that yields a high degree of error tolerance/detection and yet introduces advantageously little latency in the read paths during normal use and consumes relatively little circuit resource. The rates A, B and C can each independently be variable or fixed, e.g. (i) the slow path having corrected Y errors can output the remaining error free data at rate B making the average rate C a data dependent (stochastic) variable; and/or (ii) the zero-error path and the i fast paths each have a different rate B which is greater than C making the rate B vary depending on the path(s) taken for a particular set of symbols.

The present technique provides a blend of fast zero-error detection, fast-path error correction, slow-path error correction and fast bad-block detection that in combination are well suited to the error characteristics of a NAND memory. Example embodiments of the present invention will now be described, by way of example only, with reference to the accompanying drawings in which:

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates a memory controller for a NAND memory array in accordance with a first example embodiment;

FIG. 2 schematically illustrates a memory controller for a NAND memory array in accordance with a second example embodiment;

FIG. 3 illustrates decoder latencies for different decoder configurations as a function of the NAND bit error rate (BER);

FIG. 4 is a high level flow chart illustrating the decoder function in accordance with the example embodiment of FIG. 1;

FIG. 5 schematically illustrates the structure of a BCH decoder function;

FIG. 6 is a high level flow diagram illustrating syndrome computation;

FIG. 7 is a high level flow diagram illustrating a zero error test;

FIG. 8 is a high level flow diagram illustrating a Berlecamp-Massey algorithm;

FIG. 9 is a high level flow diagram illustrating a parallel exhaustive search for error addresses;

FIG. 10 illustrates a circuit for computing the partial remainders and the syndromes associated with forward error correction; and

FIG. 11 illustrates a circuit that may be used to implement the Berlecamp-Massey algorithm and a parallel exhaustive search in a single set of registers with associated connectivity.

### DESCRIPTION OF THE PREFERRED EMBODIMENTS

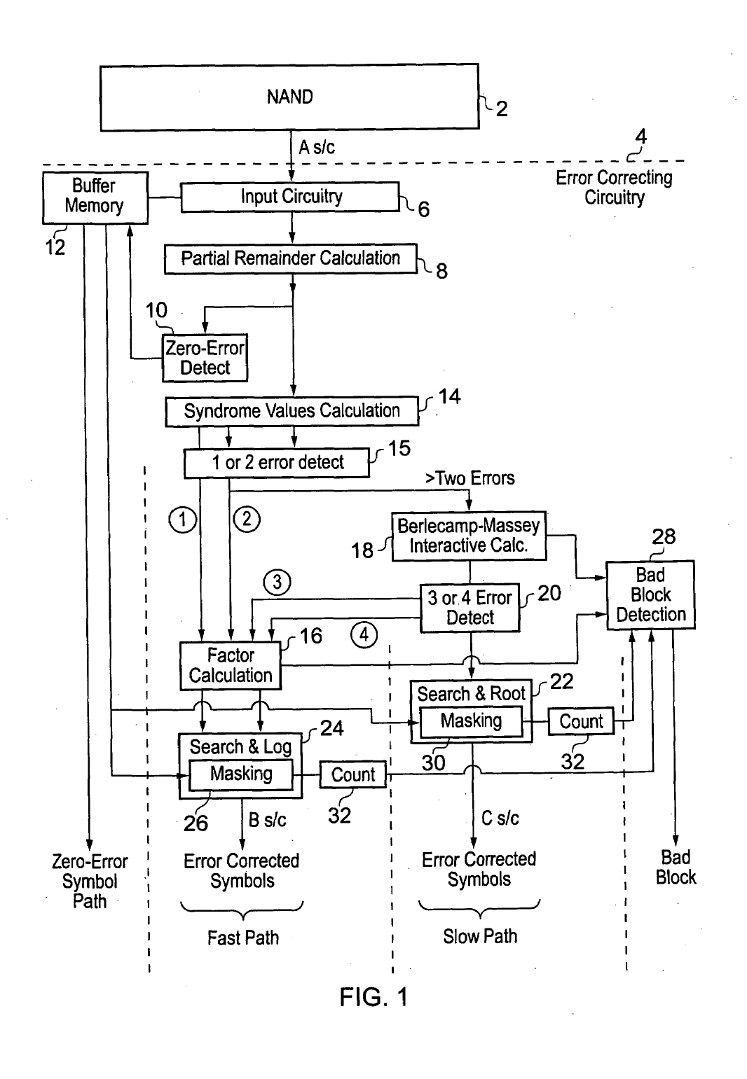

FIG. 1 schematically illustrates a first embodiment of a system including a NAND memory array 2 coupled to a memory controller 4 that includes error detecting circuitry. The error detecting circuitry includes input circuitry 6 for accepting blocks of symbols as a stream of symbols at a rate of A symbols per cycle and forwarding the data to both partial remainder calculating circuitry 8 and a buffer memory 12. The parity symbols are only forwarded to the partial remainder calculating circuitry 8. The partial remainder calculating circuitry 8 receives the symbols read from the NAND memory and calculates Q partial remainder values resulting from dividing the block of symbols by one of Q factors of a generator polynomial (which defines the used BCH code) and Q products of factors of a generator polynomial, Q being an integer greater than 1 and the partial remainder values being indicative of any symbol-errors within the block of symbols.

Fast zero-detecting circuitry 10 is coupled to the partial remainder circuitry 8 and determines from the partial remainders that the block of symbols has values corresponding to zero symbol errors being present. This zero-error fast detection can then be used to trigger the output of the data, thus excluding the parity symbols, that was previously read from the NAND memory array 2 into the buffer memory 12. The zero-error detecting circuitry is responsive to the partial remainders calculated by the partial remainder calculation circuitry 8 all having a zero value to detect that the block of symbols contains zero symbol errors.

The partial remainder calculation circuitry is relatively computationally intensive and accordingly to reduce read latency it may be provided with a plurality of parallel computational paths in order that the partial remainder values can be calculated in respect of A symbols per processing cycle so as to keep up with the rate at which symbols are read from the NAND memory array 2 by the input circuitry 6.

Syndrome calculation circuitry 14 is coupled to the partial remainder calculation circuitry 8 and responds to the partial remainder values calculated calculates S syndrome values. The S syndrome values can be used to calculate an error locator polynomial in accordance with forward error correction techniques. One or two error detecting circuitry 15 tests for the presence of one or two errors with the block.

In the example illustrated, error correction in respect of blocks of symbols containing one, two, three or four symbol errors can be performed using fast-path error correcting circuitry. In respect of blocks containing one and two symbol errors one or two error detecting circuitry 15 directly calculates a determination that one or two symbol errors occurred during the generation of a further 2T−S syndrome values thereby validating an associated error locator polynomial in respect of the lower-most error number value i up to and including the value M0. In this example embodiment this corresponds to the one and two error cases. If successful, then one or two error detecting circuitry 15 triggers the factor calculation circuitry 16 to treat these one symbol and two symbol error cases via a fast path. In the case of three or four symbol errors, iterative circuitry 18 performing the Berlecamp-Massey algorithm calculates the associated error locator polynomial and if successful detector circuitry 20 triggers the factor calculation circuitry 16 to treat these three symbol and four symbol error cases via the fast-path.

The factor calculation circuitry 16 provides for the direct calculation/validation of the factors of the error locator polynomial up to and including the value M. In this example this is the one error, two error, three error and four error cases. The iterative circuitry 18 forms part of the fast-path calculation in respect of blocks for which the number of symbol errors is greater than M0 and less than or equal to M (M0<=M). In this example the iterative circuitry handles part of the fast-path processing in respect of the three error and four error cases. Thus, the zero error case is handled by the fast zero-error detecting circuitry 10. The case where the number of symbol errors is any of one, two, three or four is handled by the fast-path error correcting circuitry, which may involve the iterative circuitry 18 and the three or four error detecting circuitry 20.

When there are greater than M symbol errors present, but fewer than E symbol errors (which is one of configured or programmed limit to the number of symbol error that can be corrected, the slow-path error correcting circuitry which includes the iterative circuitry 18 and the search and root testing circuitry 22 serves to provide error correction for any permutation of Y symbol errors occurring within such blocks. It will be appreciated that the fast-path error correcting circuitry 16, 18, 20 is able to generate a stream of corrected symbols at a rate of B symbols per cycle, which is greater than the rate of C symbols per cycle at which the slow-path error correcting circuitry 18, 20, 22 is able to generate a stream of corrected symbols.

Search and logarithm calculating circuitry 24 within the fast-path serves if i symbol-errors are detected to be responsive to the correspondingly computed (by block 16) i factors of the identified error locator polynomial. Since the error addresses are related to the discrete logarithm of the factors, they may be used to generate mask values for fast-path masking circuitry 26.

Also coupled to the iterative circuitry 18 is fast bad-block detecting circuitry 28 which serves to detect if a block has greater than E symbol-errors (i.e. greater than the configured or programmed limit to the number of symbol errors to be corrected) and accordingly cannot be corrected by the error correcting circuitry within the memory controller 4. In this case the fast bad-block detecting circuitry may be formed by virtue of the remaining 2T−2E syndromes not used for the error correction computation and serve to guarantee bad-block detection up to when the block contains T or less symbol errors, where T is greater than E and is related to the amount of redundant data which was added to the block to support the forward error correction. The fast bad-block detection circuitry 28 is responsive to a failure to calculate an error locator polynomial by the iterative circuitry 18 or a failure to calculate the factors by the factor calculation circuitry 16 so as to detect a bad-block in a low latency fashion. Bad-block detection may also be triggered by the fast-path mask generating circuitry 26 or slow-path mask generating circuitry 30 being unable to generate masks with the appropriate accumulated symbol weight counted by block 32 exactly matching the presumed number of symbol errors.

It will be appreciated that the zero-detecting circuitry, the fast-path error correcting circuitry, the slow-path error correcting circuitry and the fast bad-block detecting circuitry can process the blocks of symbols at least partially in parallel so as to increase their throughput and reduce latency. The degree of parallelism used will be a tradeoff between the required latency and the circuit overhead.

The error correcting circuitry within the memory controller 4 performs error correction upon symbols which are read from the NAND memory array 2 in blocks of symbols.

The fast bad-block detection reliability may be enhanced by augmenting the used encoder generator polynomial with a factor f(z)=z−1, corresponding to a parity bit, and computing the partial remainder of this factor within the partial remainder circuitry 8. The resulting additional parity syndrome is then used in the blocks 10, 15, and 20 to make the activation of the zero error path and the fast path more reliable, and with block 28 to make the fast bad-block detection more reliable. In the example embodiment a fast parity checking circuitry 32 checks if the degree of the error locator polynomial has the same parity as the parity of the block of data symbols. If the parities differ, then this indicates a bad-block. Thus, the fast parity checking circuitry 32 is provided to be responsive to a comparison of the degree of the error locator polynomial and a parity symbol determined from the block of symbols by the partial remainder calculation circuitry 8 so as to early terminate the error correction processing when appropriate.

The syndrome calculating circuitry uses parallel computational paths such that the syndrome value calculation can be performed in respect of A symbols per processing cycles to keep up the data throughput. The iterative computing circuitry 18 can use both parallel and pipelined hardware to accelerate its processing so as to again keep up the processing rate, although this will be less in the slow-path than is achieved by the fast-path. The slow-path using the iterative circuitry 18 and the root search calculation circuitry 22 outputs a stream of corrected symbols at a rate of C symbols per cycle.

The syndrome value calculation circuitry 14 serves to multiply vectors of symbols interpreted as a binary vector with a binary matrix as part of calculating the syndrome values. In this context the binary matrix can have elements with values modified to compensate for the effects of non-data alignment in the symbols received by the input circuitry 6. Compensating for such alignment effects with adjustments to the binary matrix increases efficiency as it enables the data to be read at the output of the error correcting circuitry more efficiently. The binary matrix values may also be modified to compensate for pipelining delays through the error correcting circuitry.

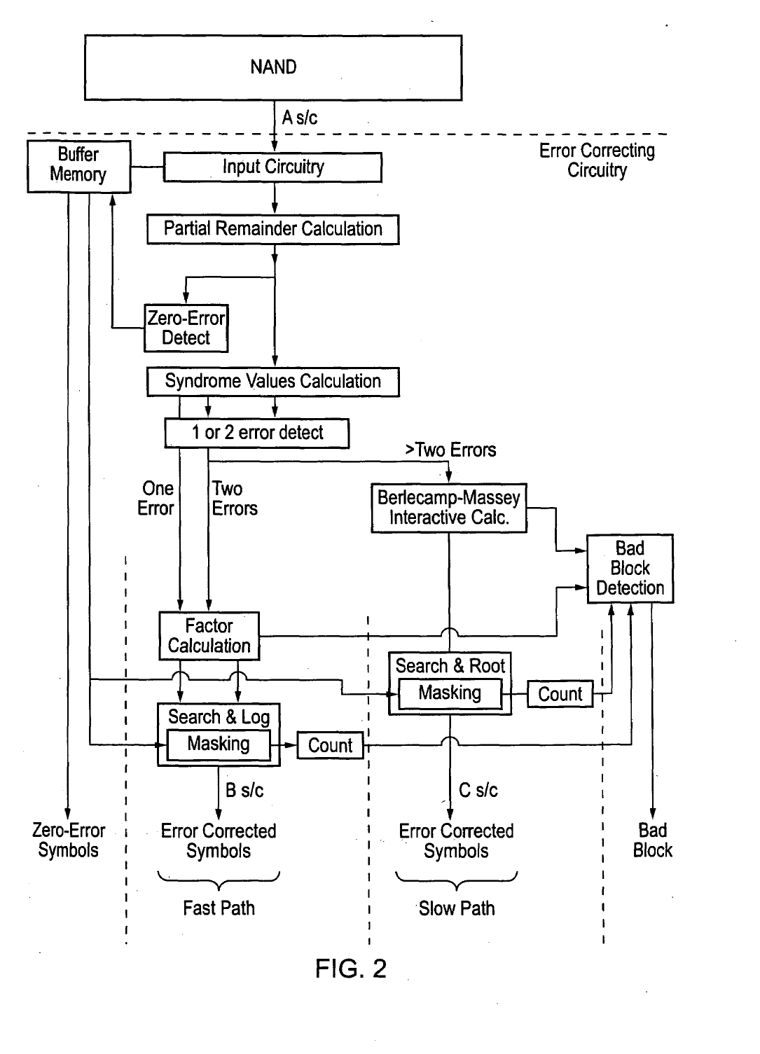

FIG. 2 illustrates a second example embodiment. This second example embodiment follows the FIG. 1 embodiment except that the fast path only operates in respect of one error and the two error cases. Thus, in particular, in this second example embodiment M0==M and the iterative computing circuitry 18 is not shared by the fast path and the slow path. For cases greater than two errors the slow path is used.

The following gives a description of a binary BCH encoder and decoder for use within a memory controller for reading NAND memory. This example follows the embodiment of FIG. 1 with M=2 and M0=1.

1.3 Terms and Abbreviations

| Term | Meaning |
|---|---|
| BCH | Bose Hocquenghem Chaudhuri (codes) |
| BER | Bit Error Rate |
| BIST | Build In Self Test |
| CRC | Cyclic Redundancy Check |
| DFT | Discrete Fourier Transform |
| EEC | Error Control Coding |
| FEC | Forward Error Control (coding) |
| FER | Frame Error Rate |
| FFT | Fast Fourier Transform |
| GF | Galois Field |
| RS | Reed Solomon (codes) |

1.4 Scope

This document describes the API and behaviour of the binary BCH reference encoder and decoder for application in a hardware accelerator for multi-level NAND-flash error correction.

1.5 Executive Summary

The key timing properties of the enhanced binary BCH encoder and decoder are listed in Table 1 below.

The numbers in Table 1 have been computed for the largest supported error correcting capability of 16 errors. The cycle counts are nominal values which may very depending on low-level implementation details. It assumes single cycle operation in all innermost algorithmic loops, i.e. full parallelisation in HW of those loops as well as single cycle per byte read access and instantaneous (burst) writes.

TABLE 1
The enhanced binary BCH encoder and decoder cycle counts

| Function/case | cycles | Pr. BER = 1.0e−3 | Pr. BER = 5.0e−04 | Pr. BER = 1.0e−4 |
|---|---|---|---|---|
| encode | 539 (512 + 27) | 100% | 100% | 100% |
| Decode no errors | 540 (539 + 1) | 1.35% | 8.88% | 65% |
| Decode 1 error best case | 560 (540 + 20) | 5.81% | 21.5% | 28% |
| Decode 1 error typical⁴ | 590 (540 + 50) | 5.81% | 21.5% | 28% |
| Decode 1 error worst case | 622 (540 + 82) | 5.81% | 21.5% | 28% |
| Decode 2 errors best case | 872 (540 + 332) | 12.5% | 26.1% | 6.02% |
| Decode 2 errors typical⁵ | 954 (540 + 414) | 12.5% | 26.1% | 6.02% |
| Decode 2 errors worst case | 996 (540 + 456) | 12.5% | 26.1% | 6.02% |
| Decode >2 errors best case | 830 (540 + 290) | 80.3% | 43.5% | 0.98% |
| Decode >2 errors typical^{6,7} | 2442 (540 + 1902) | 80.3% | 43.5% | 0.98% |
| Decode >2 errors worst case | 2980 (540 + 2440) | 80.3% | 43.5% | 0.98% |

The count for decoding does not include data output from the device. In the cases of >2 errors this process can be done while decoding. In the cases of one or 2 errors, the error address computation always precedes output generation.
The last three columns indicate the probability of occurrence for a particular decode scenario as a function of the BER statistics of the memory device. Note that for a BER <1.0e−4 the likelihood of having more than one error per sector becomes very small. For a BER <1.0e−5, the probability of having any error at all becomes very small.
⁴The variability is due to the search in the fast logarithm.
⁵The variability is due to the search in the fast logarithm, the constant increase due to both the Berlecamp-Massey algorithm and the fast quadratic equation solver.
⁶The variability is due to the exhaustive search, the constant increase due to the Berlecamp-Massey algorithm.
⁷The typical cycle count is an approximation, as the true average depends on the Bit Error Rate (BER)

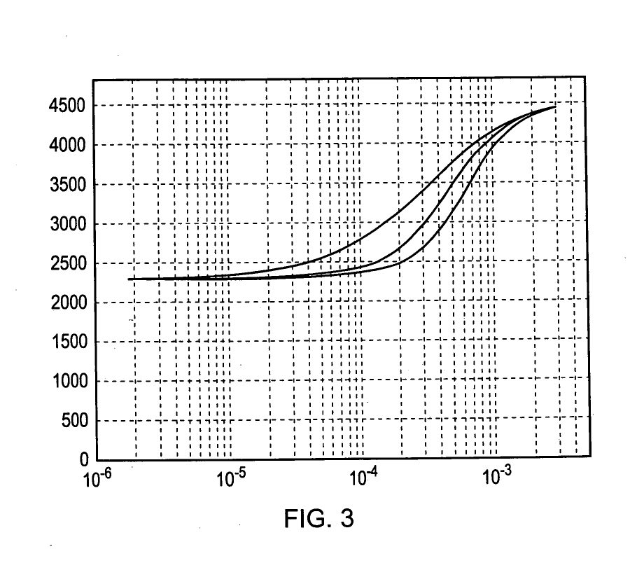

FIG. 3 below illustrates the average decode latency as a function of input BER for decoder realisations with realistic read and write access speeds and with or without single or two error specialisations.

The minimum latency is determined by the NSND access rate, here modelled as 4 cycles per byte. The bus access rate is limited to 4 bytes per cycle. The maximum latency is determined by the throughput of the search for error addresses. The top curve is a decoder with no optimisations. The next two lower curves represent decoders with only a single error path respectively one with also a two error path. The bottom curve requires that the Berlecamp-Massey algorithm is bypassed for the two error case. Note that the latter model is only realised in the r0p2 reference code.

With a error correcting capability of 16 errors, which is the upper limit when using a 27 byte extended parity region the FER (Frame Error Rate) is <3e-6 for a BER of 1e-3. A FER <6e-6 is realised when using a 16 byte parity region at a BER of 1e-4 with a capability of correcting 5 errors.

A frame error is the event where the decoder signals that the sector cannot be successfully corrected₈. ₈This is also known as a decoder failure, see section 3.6.

2 Introduction

This document describes the specifics of all algorithmic modules in the NAND-FEC algorithm. The error correction is based on an enhanced binary BCH code. Enhanced refers to the addition of a single parity bit, which increases the minimum distance of the code by one, but by means of modifying the generator polynomial, rather than computing a parity bit over a normally encoded data vector.

Section 3 lists the functional steps as they are represented in the reference algorithm.

Section 4 defines the interface of the main encoder, error checker and decoder. Section 5 describes the modules of the main functions.

This document describes the interface and operation of the r0p2 architecture true model. Note that this model deploys statically assigned resources, the more recent r1p0 model features dynamically assigned resources. However all statements in this document referring to the need to test the size of the resources prior to code execution apply equally to the r1 p0 model.

In addition in section 6 the API of support functions for trace based debug and AXI stimuli file generation are described.

3 NAND-FEC General Overview

The NAND-FEC algorithm is an enhanced binary BCH Forward Error Control (FEC) algorithm. The data block-size to be encoded is fixed and equal to K_{b}=4096-bits (see ref[1] and ref[2]). The error correcting capability, i.e. the number of errors that can be corrected is 1 to 16. This range requires that the Galois field which defines the BCH code is GF(8192), thus with a 13-bit finite field number representation (see ref[1] and ref[2]). This implies that for the decoder, unless otherwise stated, all computation is performed on 13-bit GF(8192) arithmetic. However since the generator of the BCH code is defined in GF(2) all computation in the encoder is binary unless otherwise stated.

3.2 Definition of the Code

The number of parity bits P_{b} depends on the error correcting capability T, and is given by the following formula:

P_{b}=13·T+1 (1)

The total number of bits per block N_{b} equals:

N_{b}=K_{b}+P_{b}=4096+13·T+1 (2)

When the parity bits are stored in multi-bit words of B bits per word the storage requirement N_{B} is:

$${N}_{B} = {K}_{B} + {P}_{B} = ⌈ \frac{4096}{B} ⌉ + ⌈ \frac{13 \cdot T + 1}{B} ⌉ \qquad ( 3 )$$

Note that equation (3) implies that both the data and the parity are separately word aligned. For the storage alignment specification see section 3.3 below. The enhanced binary BCH code is defined by the following set of polynomial factors:

TABLE 2
Definition of the enhanced binary BCH code

| factor | root | Polynomial (b₀, b₁, . . . b₁₃) | Conjugate roots |
|---|---|---|---|
| g0 | 0 | 11 | 0 |
| g1 | 1 | 11011000000001 | 2, 4, 8, 16, 32, . . . |
| g2 | 3 | 10001101011001 | 6, 12, 24, 48, 96, . . . |
| g3 | 5 | 11001001100101 | 10, 20, 40, 80, 160, . . . |
| g4 | 7 | 11110010111001 | 14, 28, 56, 112, 224, . . . |
| g5 | 9 | 10000111100011 | 18, 36, 72, 144, 288, . . . |
| g6 | 11 | 11000101110001 | 22, 44, 88, 176, 352, . . . |
| g7 | 13 | 10011110000011 | 26, 52, 104, 208, 416, . . . |
| g8 | 15 | 11111101010001 | 30, 60, 120, 240, 480, . . . |
| g9 | 17 | 11111111111101 | 34, 68, 136, 272, 545, . . . |
| g10 | 19 | 10010100010111 | 38, 76, 152, 304, 608, . . . |
| g11 | 21 | 11001011100111 | 42, 84, 168, 336, 772, . . . |
| g12 | 23 | 11100100000111 | 46, 92, 184, 368, 736, . . . |
| g13 | 25 | 10111010101011 | 50, 100, 200, 400, 800, . . . |
| g14 | 27 | 10101000110011 | 54, 108, 216, 432, 864, . . . |
| g15 | 29 | 10100010111111 | 58, 116, 232, 464, 928, . . . |
| g16 | 31 | 10110010101111 | 62, 124, 248, 496, 992, . . . |

The binary polynomial factor gₜ(z) is defined as:

$${g}_{t} ( z ) = {\sum }_{n} {b}_{n , t} {z}^{n} \qquad ( 4 )$$

Thus:

g₁(z)=1+z+z³+z⁴+z¹³ (5)

The polynomial g₁(z) is also the primitive polynomial that generates the field GF(8192) used by the decoder.

The binary generator polynomial G(z) for a T error correcting code with minimum distance 2T+2 is defined as:

$${G}_{T} ( z ) = {g}_{0} ( z ) \cdot {\prod }_{t = 1}^{T} {g}_{t} ( z ) \qquad ( 6 )$$

All factors except g₀ have degree 13, g₀ has degree 1; It defines an accumulator and hence computes a parity bit.

3.3 Data Storage and Alignment Specification

Binary data is stored in multi-bits words following natural or LSB order. Thus the bit vector d[N]:

d[0],d[1],d[2],K,d[N−2],d[N−1]

Is stored as a B-bit word vector D[M] with:

$$M = ⌈ \frac{N}{B} ⌉ \qquad ( 7 )$$

Where ┌ ┐ denotes the ceil( ) function, i.e. which rounds to the next higher integer.

D[0],D[1],D[2],K,D[M−2],D[M−1]

According to D[k]=[MSB down to LSB]:

D[k]=[d[kB+B−1],d[kB+B−2],K,d[kB+2],d[kB+1],d[kB]]

And in case M*B>N, i.e. the last word is not completely used:

D[M−1]=[0,0,K,0,d[N−1],d[N−2],K,d[(M−1)B+2],d[(M−1)B+1],d[(M−1)B]]

Thus the unused (padding) bits are set to zero. In the case the padding bits are involuntarily altered, or not read, they shall either be reset, regenerated or treated as zero in all circumstances.

Note that within the definitions for the binary BCH code, d[0] corresponds to the highest order coefficient of the polynomial representing the data. This aspect may require re-alignment of the data for efficient FEC processing, depending on the used algorithm.

Specifically:

D[0]=[d[MB−N−1],d[MB−N−2],K,d[2],d[1],d[0],0,K,0,0]

M

D[M−1]=[d[N−1],d[N−2],K,d[N−B+2],d[N−B+1],d[N−B]]

Thus where the data is re-aligned to have the M*B−N zeros as lead in to the data. However in the current model re-alignment is altogether avoided by modifying the BCH algorithm.

Q-ary data, for example 2-bit per word quaternary data, is first interpreted as a bit-vector according to the above convention and subsequently packed into a B-bit word vector. This means that B-bit word do not necessarily hold an integer number of Q-ary input data elements.

d₂[k]=d[k]

d₄[k]=[d[2k+1],d[2k]]

M

d_{Q}[k]=[d[qk+q−1],K,d[qk+1],d[qk]]

Where:

q=²log(Q) (8)

In the subsequent sections some of the encoder and decoder basic operations are explained in terms of binary matrix-vector operations. The addressing conventions used for matrix and vector conventions are standard, i.e. the top left element of a matrix M has row and column address zero. When data in a binary matrix is packed for efficiency reasons, the packing is by column vector. Thus a matrix M with R rows and c columns can be represented as a set of c vectors of length R. The addressing of the data elements in the vector is according to the above conventions, thus the data element at row address zero can be found on the LSB of the packed vector.

When the number of data bits in a packed column of size R of a matrix exceeds the number of available bits in the C99 supported data type used for packing, the packed column is represented by an array of words, with addressing identical to the above conventions.

3.6 Decoder Operation

The decoder is a variant of a Berlecamp-Massey based BCH decoder algorithm optimised both for binary data and low latency for data vectors with zero, one or two errors. This section gives only a brief outline of the algorithm, for a more detailed description see the description of the decoder main function “ebch2_d_nandfec( )” in section 4.3.

The first processing step is the computation of the modified syndromes, which corresponds to a partial modified DFT of the data vector. To make use of the fact that the input data is binary, the syndromes are not computed directly from the data, but from the remainder of the data when divided by the individual factors of the generator polynomial. This is because, contrary to the data, the DFT coefficients are elements of GF(8192). The syndromes are modified to compensate for the fact that the code is shortened and to compensate for data alignment (see section 3.3). The first syndrome which corresponds to the parity check enhancement is simply the sum of all data and parity bits and is thus an element of GF(2). All this processing is performed in a single module “ebch2_dft_nandfec” described in section 5.3.

The syndromes are subsequently evaluated to test for three cases using “ebch2_tst_nandfec” in section 5.4:
No errors,
A single error,
Multiple errors.

When no errors are detected the decoder operation is completed. Otherwise errors are detected and a correction attempt can be undertaken.

When a single error is detected, the error address can be determined directly from the second syndrome.

For the other cases the error correction algorithm requires the computation of the error locator polynomial and is based on a division free version of the Berlecamp-Massey algorithm optimised for the binary case. It is described in Algebraic Codes for Data Transmission by R. E Blahut (ISBN 0 521 55 374 1) section 7.2. The error locator polynomial is computed by the module “ebch2_ber_nandfec( )” explained in section 5.5.

As a final step the error addresses are computed from the error locator polynomial. This operation corresponds to finding the (logarithms of the) roots of this polynomial. For the special case of a single error the search is accelerated by applying a fast finite field logarithm directly on the second syndrome; “bch2_log_nandfec( )” given in section 5.6. For the multiple errors further optimisations are introduced:
The two error case,
More than two errors,

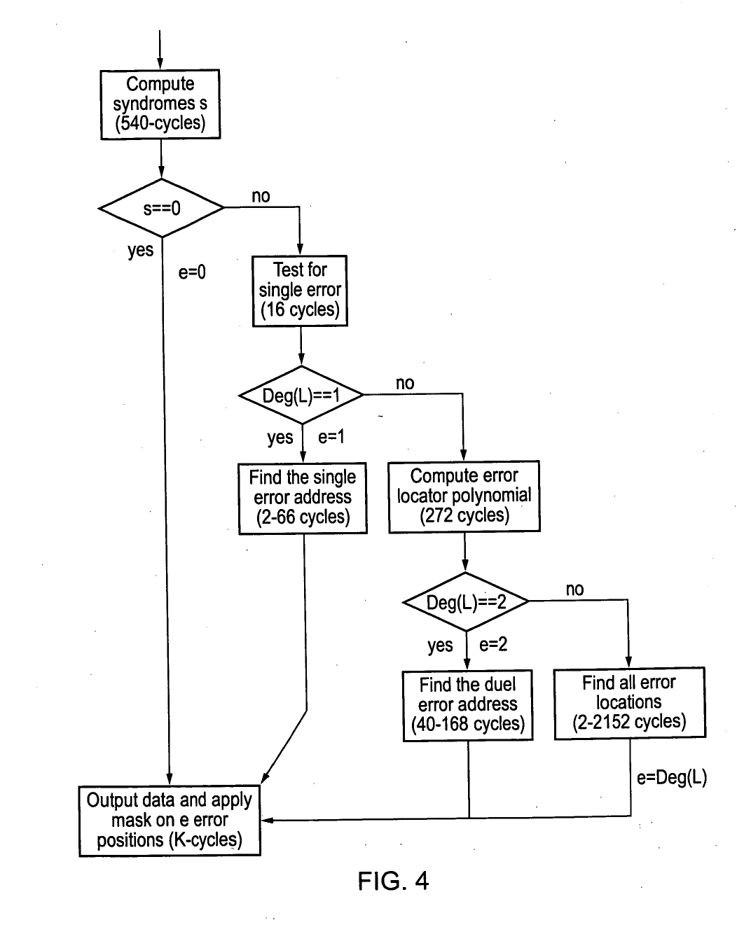

In summary the high level flow chart of FIG. 4 applies to the decoder function.

For low order polynomials, the roots can be computed directly from the coefficients of the polynomial with formulas which are specific to finite field arithmetic. In particular the case of two errors is very simple, and the solutions are computed with the function “ebch2_slv2_nandfec( )”, described in section 5.8.

For all other cases the error address are searched in the conventional exhaustive way, but made more efficient by using dedicated constant finite field multipliers “bch2_mul_nandfec( )” described in section 5.7. This approach can be accelerated by hardware duplication and using this hardware to execute parallel searches. The method used in the decoder features a two-fold parallel search, for the even and odd addresses.

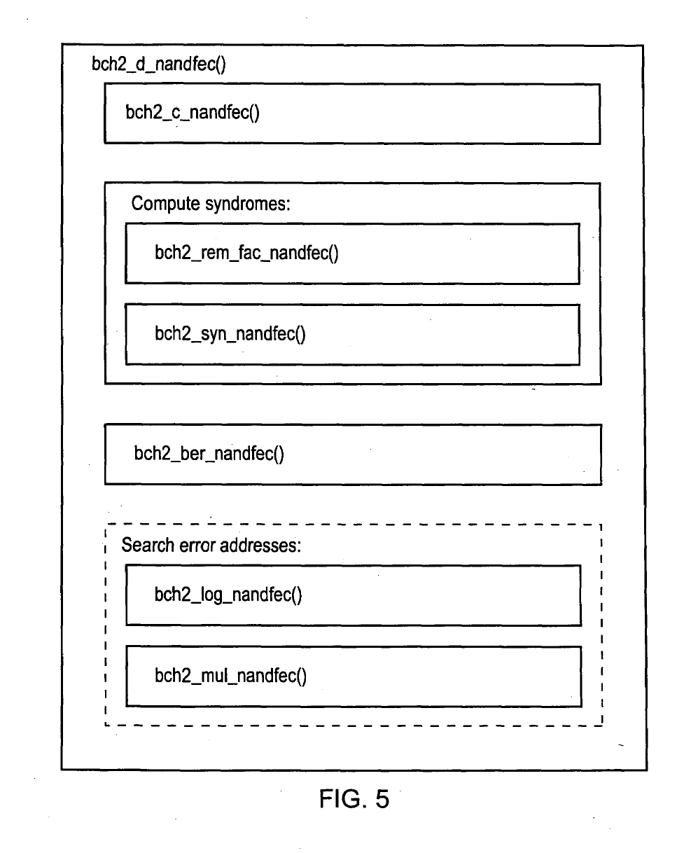

The decoder of FIG. 5 can be parameterised to limit the number of errors that may be corrected E to be below the capability T of the algorithm. This feature will effectively yield more erroneous frames that might have be been corrected, but it reduces the probability that an uncorrectable error pattern is not detected, and thus that a corrupt frame is signalled as being free of error. See also section 4.3 for details on error detection and reporting.

The event that the decoder detects an uncorrectable pattern and correctly reports this, is called a decoder failure. The undetected event where the decoder erroneously corrects such a pattern is called a decoder error. All successful decoding actions with or without the presence of errors is called a decoder success.

The decoder is guaranteed to correct frames with up to and including E errors, with E<=T. This signals a decoder success.

Because the code is enhanced, the decoder is also guaranteed to detect frames with E+1 up to and including T+1 errors. In those occurrences the decoder correctly signals a decoder failure. Note that the decoder will detect this situation before any data is send.

The decoder will also detect most other frames with more than T+1 errors, and signal a decoder failure, but cannot detect all thus patterns. This decoder error case is a property of the BCH code and not a property of the implementation. The probability of a decoder error however is very small and approximately 2−Nₚ for random patterns. Also note that the detection of a decoder failure in this case may occur both before and after data has been send.

Note that the decoder only acts on the N_{b} data- and parity-bits, thus never on any eventual padding bits (see section 3.3). Besides, although the decoder must track and account for errors within the size P_{b} parity section, it is not required to correct and emit those bits.

4 BCH2 FEC API

In this chapter the interface of the decoder function is specified. All other binary BCH codec specific sub-routines are described in chapter 5. The interface of the functions “ebch2_e_nandfec( )” and “ebch2_d_nandfec” has been enhanced to automatically generate reference stimuli in the AXI readable m3i file format. Both functions also contain an example main function, which operates by reading back the stimuli and comparing the output to the reference. Note that at present those extensions are for example of usage only, they have not been formatted for automated testing. As such, the modules described in this chapter can best be understood as a library of enhanced binary encoder and decoder functions.

4.3 ebch2 d nandfec

4.3.1 The Function Interface

The logical interface of the binary BCH decoder function is:

ebch2_d_nandfec_error_t ebch2_d_nandfec(

| | |
|---|---|
| unsigned char | *X, |
| const unsigned short | T, |
| const unsigned short | E, |
| unsigned short | *e); |

TABLE 6
Decoder interface

| Name | type | Size/range | IO-class | Function |
|---|---|---|---|---|
| X | char * | Range = [0, . . . , 255] | IO | Pointer to an array[N] of B = 8 bit data |
| | | Size N: | | words |
| | | N = 512 + ┌(13 * T + 1)/8┐ | | |
| T | short | Range = [1, . . . , 16] | I | Value specifying the number of error |
| | | | | correcting capacity. dₘᵢₙ = 2T + 2 |
| E | short | Range = [0, . . . , T] | I | Value specifying the maximum number of |
| | | | | errors on which a correction attempt is |
| | | | | allowed |
| e | short * | Range = [0, . . . , E] | O | Value specifying the number of corrected |
| | | Size 1 | | Errors |
| return | enum | See 4.3.6 | O | Function return status |

4.3.2 Operation

The decoder is explained in terms of flow-charts of its individual components. The decoder features several accelerated compute paths to address the most probable zero, single and two error cases, while only defaulting to a slow search method for more than two errors. See FIG. 4 in section 3.6 for the relation between the modules. The detailed operation of the components of the decoder them selves are explained in the sections 5.2 to 5.8.

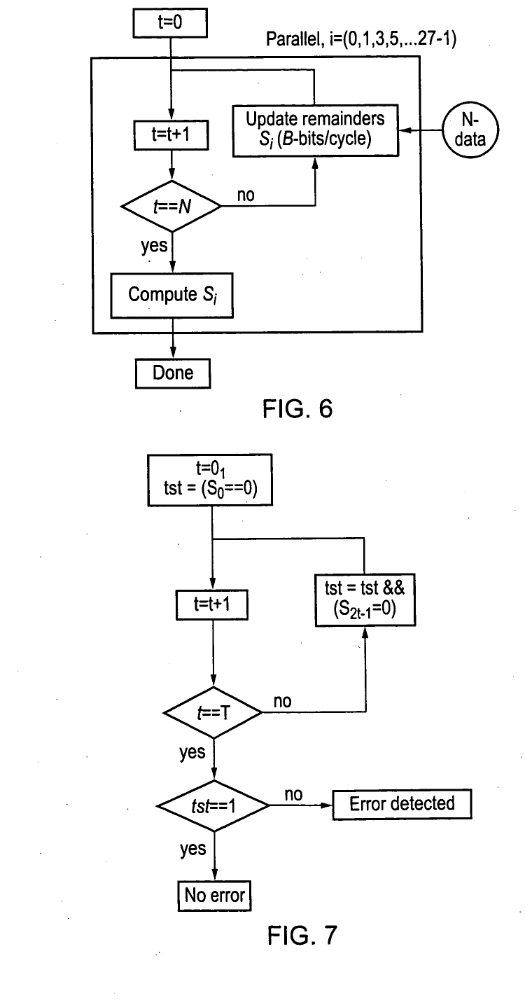

In order to meet the targeted cycle counts listed in Table 1 in section 1.5 all inner loop operations must be performed in a single cycle. This is illustrated in FIG. 6 by the “parallel” block around the basic syndrome computation. This indicates that at each cycle all the odd syndromes are updated as well as the parity syndrome S0. The even syndromes do not need to be computed, as they can be computed from the odd ones, see equation 14 below.

The test in FIG. 7 is a simple loop over the parity and the odd syndromes. Note that this implies random access to the syndrome register bank. Shift register access is likely to be more cost efficient, but this depends on the ongoing investigation of the Berlecamp-Massey algorithm, which has the most active access to the syndrome registers.

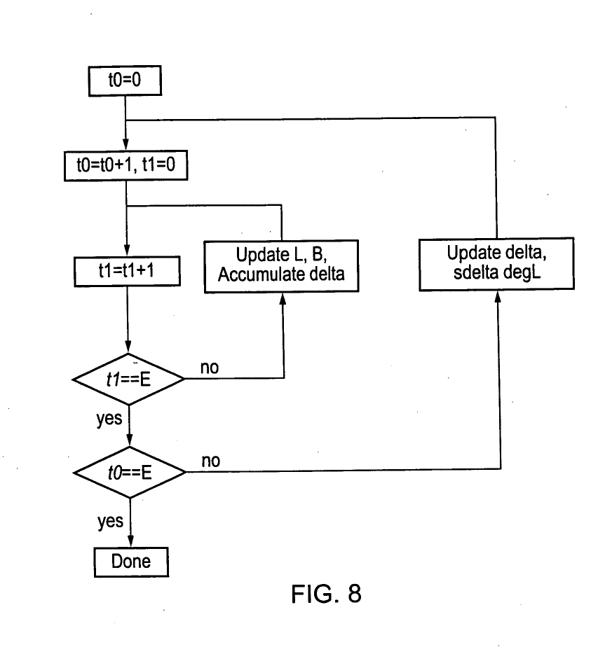

Note that the Berlecamp-Massey algorithm of FIG. 8 has a quadratic computational cost, but in E, not in T. Hence trading error detection capability for error correction capability has a positive impact on speed.

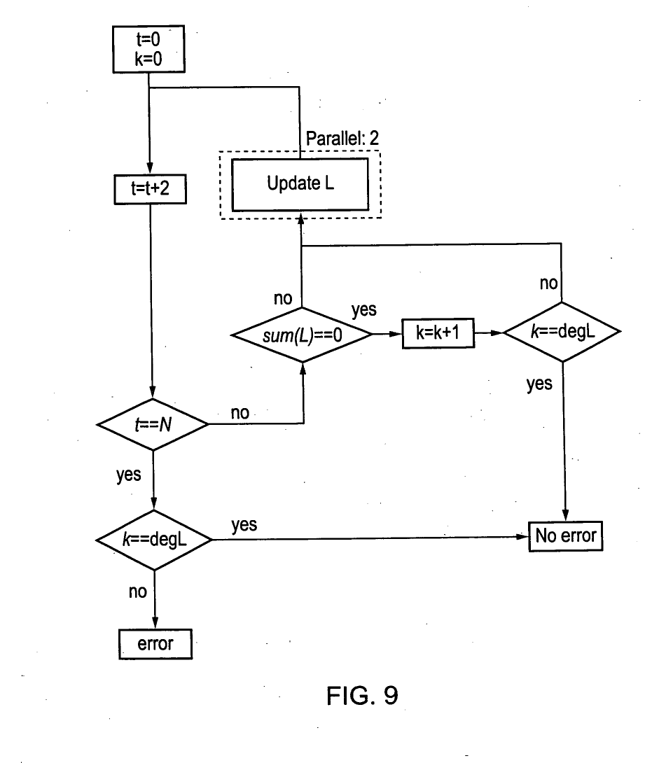

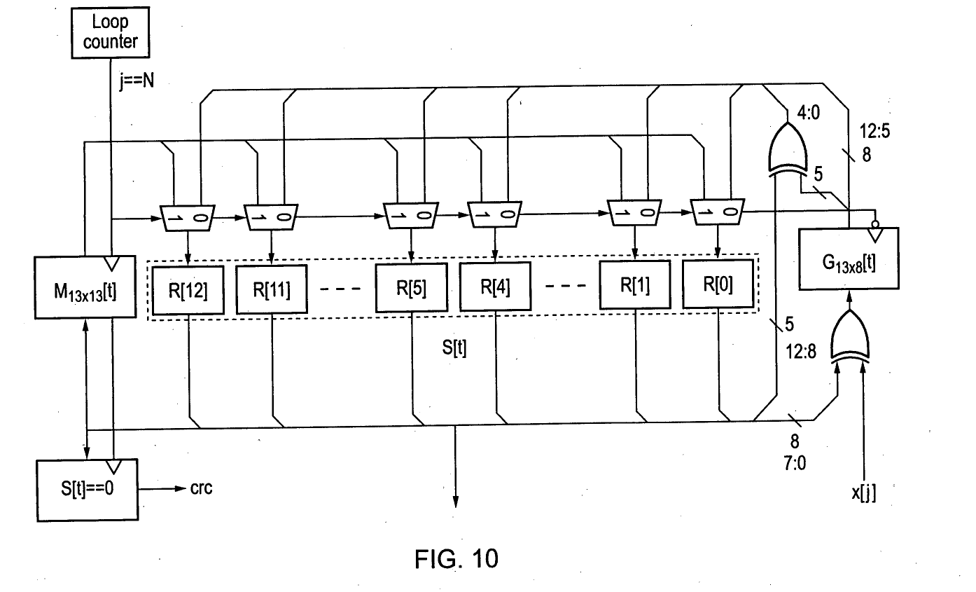

This search has a complexity proportional to the allowed error address range, which is N. This thus excludes the padding bits (see section 3.3) The “update L” block requires all coefficients of L to be updated in parallel, which has a cost of E. Thus as with the Berlecamp-Massey algorithm its complexity depends on E rather than T. The search can be further accelerated by performing multiple searches in parallel, which is the case for the current model, which has a twofold acceleration. This is indicated by the “parallel” block around the “update L” block and the fact that the loop counter advances by two as illustrated in FIG. 9.

4.3.3 The Function State- and IO Memory Specification

The decoder accesses constant tables referenced as a function of T. The decoder operates strictly within statically defined memory resources.

The decoder processes the complete set of input data of size N as a contiguous array.

4.3.4 Pre- and Post-Conditions

Before calling this function, the host must allocate sufficient memory space to the pointer X. It should also check the range of T. The output of the function is undefined when the range and/or size limits are violated.

The host must provide N8-bit data samples in X, on the addresses 0 to N−1. The last 8*(N−512)−13T−1 bits must be zero, according to the convention described in section 3.3. The data in X on the addresses 0 to 511 can be modified in an attempt to correct errors. The data on addresses 512 to N−1 may be modifiedi but not including the zero (padding) positions. This implies that error correction is not required on the parity data¹¹, yet it is required that the decoder accounts for the errors in the parity section, but not in any padding bits. Consequently, on return only the first 512 positions of X are guaranteed to contain useful data. ¹¹The current model supports error correction on the parity data, but nevertheless the status of this data is not defined when using this interface.

At most “E” errors will be corrected. “E” may not be larger than “T”. The host is responsible for validating this constraint.

The decoder provides a non-zero return status to signal a decoder failure, thus when a data error has occurred but when an unsuccessful error correction attempt has been made. The variable “e” counts the number of bits which the decoder has modified in X on the (bit index) range of 0 to 4096+13T. This thus includes the parity region, although this region may not contain useful data on return. A zero error status can either report decoder success or an (undetectable) decoder error. See section 3.6 for the definitions of success and failure.

The provided interface tests and/or sets the pre- and post conditions not covered by the return status₁₂. ¹²The interface can be compiled in debug mode to support error correction on the parity data.

4.3.5 Special Conditions

Special conditions apply due to the hierarchical method by which decoder failure detection is implemented.

In case of errors in the input frame, the typical behaviour of the BCH decoder is that it either successfully corrects those errors, or that it detects an uncorrectable error pattern, and does not modify any data. In the first case the number of corrected errors is returned in “e”, in the second case “e” is zero.

However, due to the structure of the decoder algorithm, it is also possible that an uncorrectable error pattern is detected only after the frame data is already modified. When this situation occurs, the modified positions are typically no error positions, and the decoder has thus further corrupted the frame. For “T” equal to “E”, this situation is the most likely, as now the Berlecamp-Massey module has a significant lower probability of finding errors than the (exhaustive) search, which evaluates the error locator polynomial. For only for “E<T”, more uncorrectable patterns will be trapped before the frame data has been modified and/or sent.

The occurrence of the above situation yields a non-zero error count “e” and a return status flag signalling such an uncorrectable error pattern, as described in 4.3.6 below.

For a few specific error patterns the decoder may try a successful attempt to correct more than “E” errors. This is prevented in the current decoder through the limit on “E”. This situation can occur when “E” equals “T” and this limit violation is signalled by the return status as described in 4.3.6 below.

The decoder does not test the size of statically defined memory resources.

4.3.6 Return Status

The decoder provides a return status signalling the status for normal (algorithmic) behaviour. It does not signal unexpected behaviour of the algorithm itself, such as system or memory allocation failure.

Table 7 below enumerates the applicable error codes. Any non-zero return status of the decoder function signals that an uncorrectable error pattern has been identified. This is a valid event and is known as a decoder failure (see section 3.6)

TABLE 7
Decoder error codes

| Error type | Error code |
|---|---|
| ebch2_d_nandfec_no_error | 0 |
| ebch2_d_nandfec_par_error | 1 |
| ebch2_d_nandfec_deg_error | 2 |
| ebch2_d_nandfec_cap_error | 3 |
| ebch2_d_nandfec_syn_error | 4 |
| ebch2_d_nandfec_ber_error | 5 |
| ebch2_d_nandfec_root_error | 6 |
| ebch2_d_nandfec_srch_error | 7 |
| ebch2_d_nandfec_val_error | 8 |
| ebch2_d_nandfec_num_error | 9 |
| ebch2_d_nandfec_for_error | 10 |
| Reserved | 1-15 |

The “ebch2_d_nandfec_no_error” indicates that the frame is either error free or that a successful decoding attempt has taken place₁₃ ¹³Within the limits of decoder failure probability as indicated in section 4.2.6

“ebch2_d_nandfec_par_error”, signals an uncorrectable error pattern based on the parity bit only.

“ebch2_d_nandfec_deg_error” is a Berlecamp-Massey specific error status (see 5.5.6) signalling an invalid degree or structure of the error locator prior to evaluation of the polynomial.

“ebch2_d_nandfec_cap_error” is a Berlecamp-Massey control error status (see 5.5.6). It is set when there are more errors expected than the limit “E” allows. Note that there is a small probability that this status is returned when “E” equals “T” (see also 4.3.5). This error is relatively rare and occurs when the degree of the error locator polynomial has not increased during previous cycles, and is suddenly increased beyond E.

“ebch2_d_nandfec_syn_error”, is a Berlecamp-Massey specific error status (see 5.5.6). It can only be returned when “E” is less than “T”. It signals the detection of more errors than the limit “E”, by testing the validity of the error locator polynomial on the 2×(T-E) syndromes that are not used in the Berlecamp-Massey iterations.

“ebch2_d_nandfec_ber_error” this return status is the logical OR of the three Berlecamp-Massey specific errors. A non-zero error status issued by the Berlecamp-Massy algorithm indicates an unusable error locator polynomial without the need to evaluate and test the validity this polynomial by means of the slower search procedure. Hence the decoder can abort immediately minimising latency. See section 5.5.2 for more explanation on the generation of the Berlecamp-Massey specific errors: “ebch2_d_nandfec_deg_error”, “ebch2_d_nandfec_cap_error” and “ebch2_d_nandfec_syn_error”. In the current implementation the three individual status are not available at the decoder output.

“ebch2_d_nandfec_root_error”, signals an uncorrectable error pattern detected when the number of roots of the error locator polynomial, within the allowed range, is not equal to its degree. This error return is limited for the code paths where this error can be detected before any data output.

All the previous error codes signal the detection of an uncorrectable error pattern before the decoder makes any actual correction attempts and alters or sends data. Except for the single error codepath (see FIG. 6 in section 3.6), the two error codes below are only generated after the decoder has already attempted correction and thus altered or sent data. This may result in an even more corrupted frame (see also 4.3.5).

“ebch2_d_nandfec_srch_error”, signals an uncorrectable error pattern detected when the number of roots of the error locator polynomial, within the allowed range, is not equal to its degree. Hence it is logically identical to “ebch2_d_nandfec_root_error”, but with the exception that it can only be generated during the exhaustive search (see 4.3.2, FIG. 13). Consequently the host will have received altered and incorrect data and should discard it.

The following error status are not yet used, but are defined as the application of the for binary codes technically redundant Forney algorithm may increase the decoder failure detection capability.

“ebch2_d_nandfec_val_error”, is a Forney algorithm specific error. It signals an incorrect error value detected by checking the range of the error value. If applicable, error values are computed instantaneously when during the search a presumed error address is found. In the current implementation this condition is not tested, and hence this return status is not generated.

“ebch2_d_nandfec_num_error”, is a Forney algorithm specific error. It signals a numerical exception, which can only occur in the case of a decoder failure. In the current implementation this condition is not tested, and hence this return status is not generated.

“ebch2_d_nandfec_for_error” this return status is the logical OR of the two Forney algorithm specific errors: “ebch2_d_nandfec_val_error” and “ebch2_d_nandfec_num_error”. In the current implementation those conditions are not tested, and hence this return status is not generated.

With reference to section 3.6, the decoder is guaranteed to correct up to and including E errors, and detect up to and including T+1 errors. Decoder failure is guaranteed to be signalled by the Berlecamp-Massey routine form frames with E+1 up to and including T+1 errors, using checks involving the syndromes. The last two error codes can thus only be generated in the case of more than T+1 errors in a frame. Note that the converse is not true. The “ebch2_d_nandfec_ber_error” or “ebch2_d_nandfec_par_error” can also be signalled for some frames with more than T+1 errors, thus allowing an early abort before sending any data.

5 BCH2 FEC Subroutines

This chapter describes the subroutines used by the binary BCH encoder, checker and decoder from chapter 4. All functions described in this chapter have an interface, which allows the stand-alone use of the function to facilitate algorithm development and automated testing. For example one can emulate the decoder function “ebch2_d_nandfec( )” as a function calling the modules described in this section. To have a high level interface to intermediate results to facilitate algorithm development, automated testing and specifically directed test vector generation.

In some cases the modules described here have been accelerated or modified for the sake of compute efficiency. In such cases the output of the module may deviate, either in format or numerically, from a pure textbook encoder or decoder function. In those cases, and explicitly noted in the paragraphs below, the interface is designed to translate the modified output of the module to its textbook equivalent as to allow a direct comparison of the module under test with standard high level models.

5.2 ebch2_dft_nandfec

This function computes the modified syndromes directly from the input data using an optimised realisation using division by the individual factors of the generator polynomial each having degree 13, with exception of the factor required for the parity bit, which has degree 1. This function uses the module “ebch2_syn_nandfec( )” described in section 5.3

5.2.1 The Function Interface

The logical interface of the DFT function is:

| void ebch2_dft_nandfec( | |
|---|---|
| const unsigned char | * X, |
| const unsigned short | T, |
| unsigned short | *S); |

TABLE 9
Partial divider function interface

| Name | type | Size/range | IO-class | Function |
|---|---|---|---|---|
| X | char * | Range = [0, . . . , 255] | IO | Pointer to an array[N] of B = 8 bit data words |
| | | Size N: | | |
| | | N = 512 + ┌(13 * T + 1)/8┐ | | |
| T | short | Range = [1, . . . , 16] | I | Value specifying the number of error |
| | | | | correcting capacity. dₘᵢₙ = 2T + 2 |
| S | Short * | Range = [0, . . . , 8191]¹ | O | The syndromes |
| | | Size P: | | |
| | | P = 2T + 1 | | |

Note that the syndromes are thus 13-bit valued numbers stored in a 16-bit container type.
¹The range of S[0] = [0, 1].

5.2.2 Operation

The definition of the syndromes for general BCH coding corresponds to that of a Discrete Fourier Transform (DFT), this follows from the definition:

$${S}_{t} = {\sum }_{j = 0}^{N - 1} x [ N - 1 - j ] \cdot {α}^{j \cdot t} \qquad ( 12 )$$

With α (or “alfa”) is a primitive element in GF(8192), since α^{N}=1, thus making α the N^{th} root of unity equation 12 defines a DFT. This realisation allows one to use standard algorithms for the DFT or FFT, but adapted for finite field arithmetic. A standard implementation utilises Horner's rule, which has the advantage of accessing the data X with incremental and sequential addresses.

However because a direct implementation of equation 12 would mean that all operations would be in GF(8192) despite the input data being binary, a modified approach has been realised. It is well known (see Algebraic Codes for Data Transmission by R E Blahut) that the syndromes can also be computed from a DFT over the remainder of the data polynomial X divided by the code generator polynomial, as in “ebch2_rem_nandfec( )” described in section 5.1. This would still result in a considerable amount of GF(8192) arithmetic, proportional to the length of the parity section: 13*T+1.

It is much less well known, that the syndrome Sₜ can also be computed from the remainder of the data polynomial X, divided by the factor of the generator polynomial which has a root at α^{t}. Since this remainder would be precisely of a length of 13 bits, this remainder can subsequently be converted in a single step to a 13-bit syndrome value, effectively rendering the entire DFT computation in binary arithmetic instead of GF(8192). This last step which is reminiscent to a constant finite field multiply (see section 5.7) is detailed in section 5.3.

This procedure would still literally implement equation 12, but since equation 12 is defined over exactly N bits, it would require data re-alignment when using word accelerated processing. To avoid this re-alignment the “modified” syndromes are computed instead.

$${S}_{t}^{′} = {\sum }_{j = 0}^{N - 1} x [ N - 1 - j ] \cdot {α}^{( j + offset ) \cdot t} \qquad ( 13 )$$

Equation 13 translates the syndrome information by “offset” in the code address space, and can thus be compensated for in the error address computation step of the decoder. Conversely, the “offset” can be modified further to translate the code address space such that the exhaustive search starts at the virtual address zero, thus avoiding any otherwise required initialisation. It can be shown, but this is outside the scope of this document, that all modifications can be translated to a multiplication by a constant depending only on T, which can thus be precomputed for all realisations of the decoder. See also section 5.3 for further information.

The circuit which realises the B=8 bit accelerated computation described in this section can be realised as follows:

¹⁴The range of S[0]=[0,1].

FIG. 16 depicts a single 13-bit register R. Hence for parallel computation of the syndromes T instantiations are required, each with dedicated hardwired constant multipliers to compute all odd syndromes, and an GF(2) adder to compute the parity syndrome, not depicted here. The constant multiplier G13×8 together with the bus-rippers and XOR logic implements literally equation 11 for P=13. The constant multiplier M13×13 is only activated when all data bytes x[j] has been inserted to the divider, and performs the final computation that turns the remainder into the syndrome. Consequently this circuit requires N+1 cycles to complete.

There is no need for circuitry to compute the even syndromes, as they are for binary BCH codes defined as:

S₂ᵢ=Sᵢ² (14)

Logically this operation is part of the DFT module, however for a faster implementation it is more optimal to move this operation to the error tester function described in 5.4. This optimisation is not described here, as it was preferred to keep the logical partition for clarity.

5.2.3 The Function State- and IO Memory Specification

The DFT function accesses constant tables referenced as a function of T.

The DFT input is read from all positions in X, thus both from the data and parity addresses. The data and parity are thus assumed to be stored contiguously in the array X.

5.2.4 Pre- and Post-Conditions

Before calling this function, the host must allocate sufficient memory space to the pointer X. It should also check the range of T. The output of the function is undefined when the range and/or size limits are violated.

The data re-alignment which is required for a logically correct computation has been circumvented by modification of the syndromes. As a consequence of this approach, the function accesses, and is sensitive to, all data bits in X in the range 0 to N−1. The last 8*(N−512)−13T−1 bits must be zero, according to the convention described in 3.3

The provided interface tests and/or sets the pre- and post conditions. The interface also automatically compensates the modifications to the syndromes and converts them to their “textbook” default values.

5.2.5 Special Conditions

There are no special conditions.

5.2.6 Return Status

The DFT does not provide a return status.

5.3 ebch2_syn_nandfec

This function computes a modified DFT on a binary data vector of 13 elements. This function is only used within the module “ebch2_dft_nandfec( )”.

5.3.1 The Function Interface

The logical interface of the modified binary DFT function is:

```
unsigned short ebch2_syn_nandfec(
  const unsigned short  Xr,
  const unsigned short  t);
```

TABLE 10
Syndrome function interface

| Name | type | Size/range | IO-class | Function |
|---|---|---|---|---|
| Xr | short | Range = [0, 8191] | I | A partial remainder |
| T | short | Range = [1, . . . , T] | I | The index to select of 1 out of the “T” defined |
| | | | | polynomial factors |
| Return | short | Range = [0, 8191] | O | The modified syndrome computed from Xr: |
| | | | | DFT₂ₜ₋₁(Xr) |

Note that input Xr, and the return value are thus 13-bit valued numbers stored in a 16-bit container type.

5.3.2 Operation

This function computes a specialised DFT by the following binary matrix vector multiplication.

$$[ \begin{matrix}{y}_{0} \\ {y}_{1} \\ {y}_{2} \\ M \\ {y}_{NU - 1}\end{matrix} ] = [ \begin{matrix}{M}_{0 , 0} & {M}_{1 , 0} & {M}_{2 , 0} & Λ & {M}_{NU - 1 , 0} \\ {M}_{0 , 1} & {M}_{1 , 1} & {M}_{2 , 1} & Λ & {M}_{NU - 1 , 1} \\ {M}_{0 , 2} & {M}_{1 , 2} & {M}_{2 , 2} & & {M}_{NU - 1 , 2} \\ M & M & & & M \\ {M}_{0 , NU - 1} & {M}_{1 , NU - 1} & {M}_{2 , NU - 1} & Λ & {M}_{NU - 1 , NU - 1}\end{matrix} ] \cdot [ \begin{matrix}{x}_{0} \\ {x}_{1} \\ {x}_{2} \\ M \\ {x}_{NU - 1}\end{matrix} ] \qquad ( 15 )$$

This equation looks the same as equation 15 in section 5.7, but it is different in the sense that it does not define a finite field constant, but a binary DFT instead. To see this, refer to equation 12 for N=13. From inspection it can be see that the columns of the matrix must simply be the standard (polynomial) basis representation of the finite field element αⁿ, with n={0 . . . N−1}. Despite this “only” being an interpretation of the data, the standard basis representation formally allows to define computation in this binary matrix form. This is important as we want to modify the DFT matrix to incorporate all effects of the code address space translations described in section 5.2.2. Thus:

y′=M_{offset}·M_{DFT}·x=M′·x (16)

Equation 16 states that the modified DFT, which compensates for data-realignment as well as search initialisations can be computed by synthesising a 13×13 bit constant binary multiplication, which has an expected cost of about 40 XOR gates.

Since the matrix M′ is the product of a DFT matrix and a finite field element matrix, it is full rank/has an empty null space. This means that one can have a zero syndrome output, if and only if one has a zero input. Consequently the fastest possible zero error detection procedure in the decoder can be realised by testing on the inputs of this function, rather than on its outputs.

5.3.3 The Function State- and IO Memory Specification

The syndrome function (DFT) accesses constant tables referenced as a function of t. The DFT operates strictly within statically defined memory resources.

5.3.4 Pre- and Post-Conditions

Before calling this function, the host should check the range of t. The output of the function is undefined when this range is violated. The modified binary DFT only reads the 13 LSB of Xr, the MSB are not accessed.

The return value is the DFT coefficient 2t−1 in GF(8192) from Xr representing a 13 element binary vector indexed according to the convention 3.3₁₅. ¹⁵The remaining T even DFT coefficients at 2t are computed by squaring from the T odd coefficients in the module “ebch2_dft_nandfec( )”.

The provided interface tests and/or sets the pre- and post conditions

5.3.5 Special Conditions

The DFT does not test the size of statically defined memory resources.

5.3.6 Return Status

The modified binary DFT does not provide a return status.

5.4 ebch2_tst_nandfec

This function tests for the presence of errors and the special case of a single error.

5.4.1 The Function Interface

The logical interface of the test function is:

ebch2_tst_nandfec_error_t bch2_tst_nandfec(
const unsigned short *S,
const unsigned short T);

TABLE 11
Single error tester function interface

| Name | type | Size/range | IO-class | Function |
|---|---|---|---|---|
| S | short * | Range = [0, . . . , 8191] | I | Pointer to an array[N] of field elements in |
| | | Size N: N = 2T + 1 | | GF(8192) containing the syndromes |
| T | short | Range = [1, . . . , 16] | I | Value specifying the number of error |
| | | | | correcting capacity. dₘᵢₙ = 2T + 2 |
| return | enum | See 5.4.6 | O | Function return status |

5.4.2 Operation

The test function is very simple, and is identified more as a logical entity than as a physical entity. In fact in a fastest implementation this function will swap functionality with the DFT function of 5.2. This optimisation is not described here, as it was preferred to keep the logical partition for clarity.

The test for zero errors is defined as:

$$no\_error = ( {S}_{0} == 0 ) {\prod }_{i = 1}^{T} ( {S}_{2 i - 1} == 0 ) \qquad ( 17 )$$

Meaning that the parity syndrome and all odd syndromes must be equal to zero. It is not required to test the even syndromes. Due to equation 14 above.

The single error test is a special case of the Berlecamp-Massey algorithm, and defined by

$$single\_error = {\prod }_{i = 0}^{T - 1} ( ( {S}_{2 i} \cdot {S}_{1} + {S}_{2 i + 1} ) == 0 ) \qquad ( 18 )$$

From this equation it is clear how equation 14, the generation of the even syndromes from the odd ones, can be merged with this operation. When both tests fail there are at least two errors. The converse is not true, in which case a decoder error has occured.

5.4.3 The Function State- and IO Memory Specification

The test function only accesses its input array s. For the Galois field arithmetic it accesses constant tables.

5.4.4 Pre- and Post-Conditions

Before calling this function, the host must allocate sufficient memory space to the pointer S. It should also check the range of T. The output of the function is undefined when the range and/or size limits are violated.

The provided interface tests and/or sets the pre- and post conditions.

5.4.5 Special Conditions

There are no special conditions.

5.4.6 Return Status

The tester provides the following return status.

TABLE 12
Return status of the error tester

| | |
|---|---|
| ebch2_tst_nandfec_no_error | 0 |
| ebch2_tst_nandfec_single_error | 1 |
| ebch2_tst_nandfec_multiple_error | 2 |

The value “ebch2_tst_nandfec_no_error” indicates that the there are no (detectable) errors in the data set from which the syndromes s were computed.

“ebch2_tst_nandfec_single_error” indicates the occurrence of a single error.

“ebch2_tst_nandfec_multiple_error” signals all other cases, thus also possible uncorrectable error patterns. The reliability of the tests is within the limits of the decoder error probability.

5.5 ebch2_ber_nandfec

This module computes the enhanced Berlecamp-Massey algorithm. It is specialised for binary data, and cannot be used for non-binary decoders. The enhancement refers to the improved error resilience due to tests using the parity syndrome.

5.5.1 The Function Interface

The logical interface of the Berlecamp-Massey function is:

| ebch2_ber_nandfec_error_t ebch2_ber_nandfec( | |
|---|---|
| unsigned short | *S, |
| const unsigned short | T, |
| const unsigned short | E, |
| unsigned short | *L, |
| unsigned short | *B, |
| unsigned short | *Nl); |

TABLE 13
Berlecamp-Massey algorithm interface

| Name | Type | Size/range | IO-class | Function |
|---|---|---|---|---|
| S | short * | Range = [0, . . . , 8191] | I | Pointer to an array[N] of field elements in |
| | | Size N: N = 2T + 1 | | GF(8192) containing the syndromes |
| T | Short | Range = [1, . . . , 16] | I | Value specifying the number of error |
| | | | | correcting capacity. dₘᵢₙ = 2T + 2 |
| E | Short | Range = [0, . . . , T] | I | Value specifying the maximum number of |
| | | | | errors on which a correction attempt is allowed |
| L | short * | Range = [0, . . . , 8191] | O | Pointer to an array[N] with the error locator |
| | | Size N: N = E + 1 | | polynomial coefficients in GF(8192) |
| B | short * | Range = [0, . . . , 8191] | O | Pointer to an array[N] with the auxiliary |
| | | Size N: N = E + 1 | | polynomial coefficients in GF(8192) |
| Nl | short * | Range = [0, . . . , E] | O | Value specifying the degree of L. |
| | | Size 1 | | |
| return | Enum | See 5.5.6 | O | Function return status |

Note that the coefficients of the error locator polynomial are thus 13-bit valued numbers stored in a 16-bit container type.

5.5.2 Operation

For a detailed explanation of the Berlecamp-Massey algorithm please refer to Algebraic Codes for Data Transmission by R E Blahat, including the detailed flowchart of the algorithm. The explanation of the algorithm in this section is limited to the special format of the standard algorithm for purposes of computational efficiency and throughput as well as to explain the relevance of the different error return status.

The Berlecamp-Massey algorithm is an iterative way of solving a matrix vector equation required for finding the error locations, the so called key equation, with a complexity of O(E²). One could alternatively solve the same key-equation by direct matrix inversion, but at a cost of O(E₃).

The core operator of the of the Berlecamp-Massey routine is a single cycle complex GF MAC unit effectively containing three general finite field multipliers. This unit computes the following operation:

L_{j,i+1}=L_{j,i}·Δᵢ₋₁+B_{j-2,i}·Δᵢ

Δᵢ₊₁=Δᵢ₊₁+L_{j-1,i+1}·Sₖ₋ⱼ (19)

Equation 19 defines the division free Berlecamp-Massey algorithm, which is slightly different from the textbook standard version. The standard version has fewer multiplications, at the expense of a division in the outer-loop (see FIG. 12).

This equation shows the update of L, belonging to a lower order solution, thus a small matrix involving fewer syndromes, to a higher order solution involving more syndromes. The update depends on the computed discrepancy Δ. A non-zero □ indicates that the previous L does not satisfy the new constraints due to the added syndromes. Conversely when the correct L is found, its degree equal to the actual number of errors, all subsequent Δ must be zero, provided the syndromes are known₁₆. ¹⁶Or, if we would know the L was correct, we could in fact compute the syndromes with equation (19).

The above aspect allows one to split the syndromes into two groups: The first group of size 2E can be used to compute the error locator polynomial. The second group containing the remaining syndromes can then be used to test whether Δ remains zero, thus whether L is valid for those syndromes as well. The parity syndrome “S[0]” is used exclusively for the validity test of L.

Note that it is possible that Δ is zero during one of the intermediate iterations. When this happens, the degree of L can increase by more than one on the first next iteration with a non-zero Δ. It is thus also possible that the degree of L jumps beyond the target setting E. In fact it is possible that L is valid and has a degree larger than T, in which case the decoder can indeed correct more than T errors.

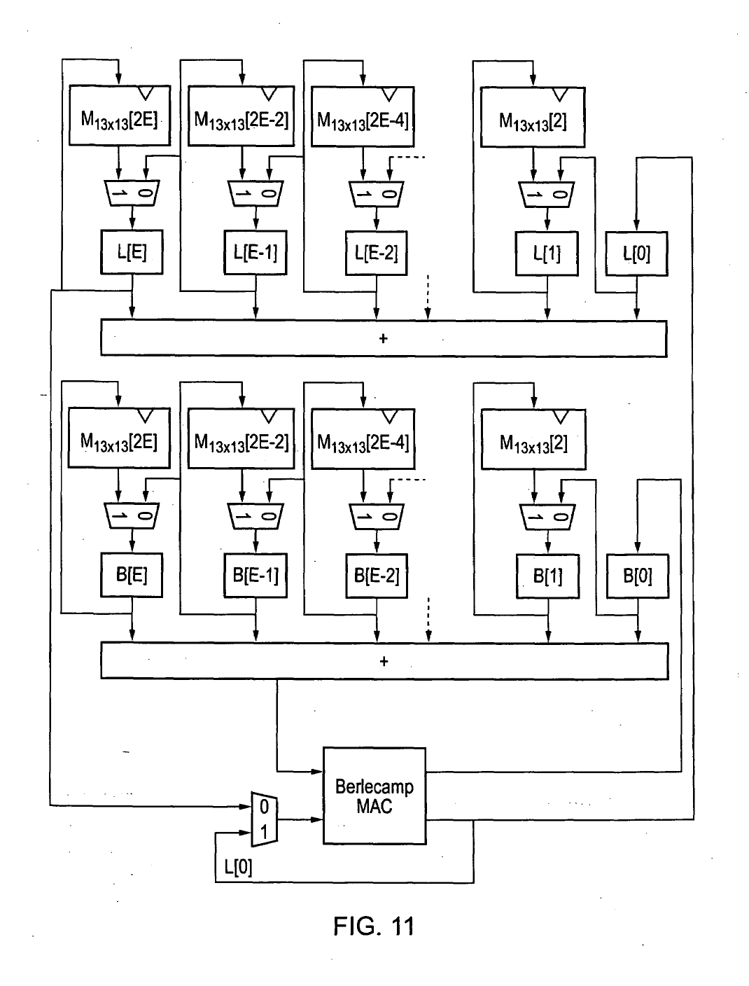

The Berlecamp-Massey algorithm is optimised for binary BCH codes, effectively halving the number of required iterations. Specifically for this implementation, the error locator register L, and the auxiliary register B are shared with the exhaustive search procedure, which is allowed by the simple connectivity requirements illustrated in FIG. 11.

During the Berlecamp-Massey iterations the register files “L” and “B” are cyclically shifted and updated. During the search the register positions are updated in-place. For the Berlecamp-Massey algorithm, the register file “L” is always read from its topmost address “E”, while “B” is read from address “E−2”. Both are written on address zero.

What is not shown for simplicity is that the “Berlecamp-MAC” block also computes the next Berlecamp-Massey discrepancy online from the new coefficient of “L” computed on the previous cycle. Note the feedback path to transport “L[0]”, which prevents the need for access to address zero of the register file “L” required for this functionality. For this computation, the current scheme requires random access to the register file “S”.

For the exhaustive search the constant associated with address zero is always one, and thus need not be implemented.

5.5.3 The Function State- and IO Memory Specification

The Berlecamp-Massey algorithm accesses constant tables and the function operates strictly within statically defined memory resources.

All 2T+1 syndromes are accessed by the function. The degree of a valid output error locator polynomial cannot be larger than E, only positions in the address range E to E+1 are written to.

5.5.4 Pre- and Post-Conditions

Before calling this function, the host must allocate sufficient memory space to the pointers S and L. It should also check the range of both T and E. The output of the function is undefined when the range and/or size limits are violated.

The host must provide 2T+1 GF(8192) syndromes in S, on the addresses 0 to 2T.

The Berlecamp-Massey algorithm gives a non-zero return status, when the computed error locator polynomial is invalid or does not satisfy the limit on its degree “E”, “NI” returns the degree of the computed polynomial also when an error is detected. “NI” is at most “E”.

This realisation of the Berlecamp-Massey algorithm is non-normalised, i.e. division free. Hence it deviates from the traditional implementation where the leading coefficient of the error locator polynomial is 1 and is treated implicitly. The now non-unit leading coefficient is stored in the array L. Thus on return all coefficients in L, on the addresses 0 to NI.

Since the search function re-uses the register files L and B, see FIG. 15, the vector B contains on output an off-set-one copy of L, such that both vectors are correctly initialised for the search procedure on return. However when the function returns a non-zero return status the contents of both L and B simply contain their last active state which is undefined outside the function.

The provided interface tests and/or sets the pre- and post conditions not covered by the return status. The inter-face also automatically normalises the output.

5.5.5 Special Conditions

For a few specific error patterns the Berlecamp-Massey algorithm may find a valid error locator polynomial with a degree larger than “T”. This is signalled in the current implementation as an error through the limit “E”.

The Berlecamp-Massey algorithm does not test the size of the statically defined memory resources.

5.5.6 Return Status

The Berlecamp-Massey algorithm provides a return status signalling the status for normal (algorithmic) behaviour. It does not signal unexpected behaviour of the algorithm itself, such as system or memory allocation failure.

Table 14 below enumerates the applicable error codes.

TABLE 14
10/23 Berlecamp-Massey error codes

| Error type | Error code |
|---|---|
| ebch2_ber_nandfec_no_error | 0 |
| ebch2_ber_nandfec_par_error | 1 |
| ebch2_ber_nandfec_deg_error | 2 |
| ebch2_ber_nandfec_cap_error | 3 |
| ebch2_ber_nandfec_syn_error | 4 |

The “ebch2_ber_nandfec_no_error” indicates that a valid error locator polynomial is found₁₇. 17 Valid within the detection capabilities of the Berlecamp-Massey algorithm. For E=T, there is a relatively high probability that an invalid polynomial is not detected by this module. Thus in this case the detection of uncorrectable patterns depends on the (exhaustive) search for roots of “L”.

“ebch2_ber_nandfec_par_error”, signals an uncorrectable error pattern based on the parity bit only.

“ebch2_ber_nandfec_deg_error” signals an invalid degree of the error locator polynomial.

“ebch2_ber_nandfec_cap_error” is set when there are more errors expected than the limit “E” allows. Note that there is a small probability that this status is returned when “E” equals “T” (see also 4.3.5 and 5.5.5). This error is relatively rare and occurs when the degree of the error locator polynomial has not increased during previous cycles, and is suddenly increased beyond E, which can occur when the discrepancy □ was zero during an intermediate iteration (see section 5.5.2).

“ebch2_ber_nandfec_syn_error”, can only be returned when “E” is less than “T”. It signals the detection of more errors than the limit “E” by testing the validity of the error locator polynomial on the 2(T−E) syndromes that are not used in the Berlecamp-Massey iterations, thus the second group as explained in section 5.5.2.

Any non-zero return status of the Berlecamp-Massey function signals that the error locator polynomial L, although with correctly computed coefficients, is flawed. This means that the roots of L do not identify error locations and thus that an uncorrectable error pattern has been identified, thus correctly signalling a decoder failure. This is guaranteed for frames with E+1 up to and including T+1 errors, but it may occur for frames with more errors as well.

5.6 bch2_log_nandfec

This function computes a discrete logarithm in GF(8192). This function is essential to achieve efficient decoding of the one and two error cases.

5.6.1 The Function Interface

The logical interface of the logarithm function is:

unsigned short bch2_log_nandfec(
const unsigned short X);

TABLE 15
Discrete logarithm interface

| Name | type | Size/range | IO-class | Function |
|---|---|---|---|---|
| x | short | Range = [0, 8191] | I | A field element of |
| | | | | GF(8192) |
| Return | short | Range = [0, 8191] | O | Log(X). |

5.6.2 Operation

Computing a finite field logarithm is a computationally hard problem. In fact this computation forms the basis of many cryptographic systems because it is so hard. A brute force implementation is simply an exhaustive search over all possible values. More sophisticated and potentially fast algorithms require either a finite field with special properties or a field generator with special properties and fairly complicated algorithms to exploit those properties. In the present implementation, it is required to use a field GF(2^{NU}) with NU=13, prime for the sake of coding efficiency, which precludes the simpler of the sophisticated methods because NU is prime.

Therefore a relatively simple semi-exhaustive method is implemented that is not exceptionally fast, but sufficiently so and feasible and applicable to moderate field sizes. To compute the logarithm n of β:

β=αⁿ (20)

One can write

β·(α^{-m})ⁱ=α^{j} (21)

Which follows from:

αⁿ=α^{i·m+j} (22)

By pre-computing a table of size [n/m] of α^{j}, the search requires only m steps, provided that one has a single cycle search over all the table entries to find a match¹⁸. This can be accomplished by using hashing functions. An explanation of hashing functions is outside the scope of this document. For this design a simple cost efficient hashing function has been created and has been exhaustively tested. ₁₈Thus the search problem has not become less, it is only split into two separate problems.

5.6.3 The Function State- and IO Memory Specification

The logarithm accesses constant tables.

5.6.4 Pre- and Post-Conditions

This function computes the logarithm of all field elements, including the log of zero. However the host should check the range of x. The output of the function is undefined, or the out-of-bound table access may occur when this range is violated. Note that for application within the enhanced binary BCH decoder the logarithm needs only to be computed within the valid range of error addresses 0 to N_{b}−1. This reduced the search range and hence reduces the worst case computation time. This optimisation is assumed in the cycle counts given in Table 1 in section 1.5.

The provided interface tests and/or sets the pre- and post conditions and it includes a BIST over the full range of the logarithm

5.6.5 Special Conditions

There are no special conditions.

5.6.6 Return Status

The logarithm does not provide a return status.

5.7 bch2 mul nandfec

This function computes a selected constant GF(8192) multiplication

5.7.1 The Function Interface

The logical interface of the constant multiplier function is:

```
unsigned short bch2_mul_nandfec(
  const unsigned short  X,
  const unsigned short  t);
```

TABLE 16
Constant multiplier function interface

| Name | type | Size/range | IO-class | Function |
|---|---|---|---|---|
| x | short | Range = [0, 8191] | I | A field element of GF(8192) |
| T | Short | Range = [1, . . . , 2T] | I | The index to select of 1 out of 2T of the |
| | | | | predefined constants alfa \hat{ }1. . . alfa \hat{ }2T |
| Return | Short | Range = [0, 8191] | O | X * (alfa\hat{ }t), alfa the primitive element of the |
| | | | | field. |

5.7.2 Operation

Constant multiplications are very efficient to compute in Galois fields of size 2^{NU}, for GF(8192), NU=13, when the standard (polynomial basis) representation is used.

$$[ \begin{matrix}{y}_{0} \\ {y}_{1} \\ {y}_{2} \\ M \\ {y}_{NU - 1}\end{matrix} ] = [ \begin{matrix}{M}_{0 , 0} & {M}_{1 , 0} & {M}_{2 , 0} & Λ & {M}_{NU - 1 , 0} \\ {M}_{0 , 1} & {M}_{1 , 1} & {M}_{2 , 1} & Λ & {M}_{NU - 1 , 1} \\ {M}_{0 , 2} & {M}_{1 , 2} & {M}_{2 , 2} & & {M}_{NU - 1 , 2} \\ M & M & & & M \\ {M}_{0 , NU - 1} & {M}_{1 , NU - 1} & {M}_{2 , NU - 1} & Λ & {M}_{NU - 1 , NU - 1}\end{matrix} ] \cdot \\ [ \begin{matrix}{x}_{0} \\ {x}_{1} \\ {x}_{2} \\ M \\ {x}_{NU - 1}\end{matrix} ] \qquad ( 23 )$$

The matrix M is thus a 13×13 binary matrix, and the input and output vectors x respectively y are 13 element (column) vectors. The matrix vector multiplication is according to GF(2) arithmetic, thus with multiplication defaulting to a bitwise AND operation, and addition to a bitwise XOR. With the matrix being constant the AND operation is not required, and the operation represented by equation 12 can be transformed to dedicated logic which on average requires not more than 2NU thus 26 XOR gates. For values of “alfa<NU”, the matrix is even sparser, and the complexity thus lower.

5.7.3 The Function State- and IO Memory Specification

The multiplier function accesses constant tables referenced as a function of t. The multiplier operates strictly within statically defined memory resources.

5.7.4 Pre- and Post-Conditions

Before calling this function, the host should check the range of t. The output of the function is undefined when this range is violated. The multiplier only reads the 13 LSB of x, the MSB are not accessed.

The return value is the multiplication of x with alfât in GF(8192).

The provided interface tests and/or sets the pre- and post conditions and it includes a BIST.

5.7.5 Special Conditions

The multiplier does not test the size of the statically defined memory resources.

5.7.6 Return Status

The multiplier does not provide a return status.

5.8 ebch2 slv2 nandfec

This function solves the roots of a quadratic polynomial in GF(8192)

5.8.1 The Function Interface

The logical interface of the logarithm function is:

```
unsigned short ebch2_slv2_nandfec(
  const unsigned short  *L,
  const unsigned short  *A);
```

TABLE 17
Quadratic equation solver interface

| Name | type | Size/range | IO-class | Function |
|---|---|---|---|---|
| *L | short | Range = [0, 8191] | I | A vector(3) with elements of GF(8192) |
| | | Size 3 | | containing a non-normalised degree-2 error |
| | | | | locator polynomial |
| *A | short | Range = [0, 8191] | O | A vector(2) with elements of GF(8192) |
| | | Size 2 | | containing the roots of L |
| Return | short | Range = {0, 2} | O | The number of found roots. |

5.8.2 Operation

This algorithm is a specialisation of a closed form solution to quadratic equations:

ax²+bx+c=0 (24)

For Galois fields of characteristic 2, thus (extension) fields of size 2^{NU}, the well known textbook solution cannot be used, but alternative finite field specific algorithms have been found. The complete derivation of the algorithm is out-side the scope of this document, see Algebraic Coding Theory by E R Berlecamp [1968] for details. The omission of the algorithmic details is compensated by the fact that the implementation has been tested exhaustively.

5.8.3 The Function State- and IO Memory Specification

The quadratic equation solver accesses constant tables.

5.8.4 Pre- and Post-Conditions

This function computes selected solutions to quadratic equations. Polynomials that have either double roots or a root at zero, thus polynomials of the forms:

f(x)=ax²+c

f(x)=ax²+bx (25)

are rejected. As a consequence the function returns a root count of either zero or two.

5.8.5 Special Conditions

This function is specialised to be able to compute the roots of a non-normalised (non monic) error locator polynomial.

5.8.6 Return Status

The quadratic equation solver returns the number of found roots, any value other than 2 signals an implicit error.

The following gives bit and architecturally accurate C code representations of the operation of the Berlecamp-Massey algorithm, the Discrete Fourier Transform (DFT) used in syndrome calculation and the output partitioning:

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

We claim:

1. A memory controller for a NAND memory array, said memory controller comprising error detecting circuitry having:
input circuitry for accepting a block of symbols as a stream of symbols at a rate of A symbols per cycle;
fast zero-error detecting circuitry responsive to said block of symbols read from said NAND memory to detect at a rate corresponding to B symbols per cycle if said block of symbols has values corresponding to zero symbol errors being present;
fast-path error correcting circuitry providing M fast computational paths, an i^{th} fast computational path of said M fast computational paths providing correction for any permutation of i symbol-errors within said block of symbols, where M is an integer value greater than zero and less than a maximum number of symbol-errors E to be corrected and i varies within a range 0<i≦M, said fast-path error correcting circuitry generating a stream of corrected symbols at rate of B symbols per cycle;
slow-path error correcting circuitry providing correction for any permutation of Y symbol-errors within said block of symbols, where Y is an integer value within a range greater than M and less than or equal to E, said slow-path error correcting circuitry generating a stream of corrected symbols at rate of C symbols per cycle, where C is less than B; and
fast bad-block detecting circuitry adapted to detect that said block of symbols is a bad-block having greater than E symbol-errors and cannot be corrected by said error correcting circuitry, said fast bad-block detecting circuitry being formed to guarantee bad-block detection up to when said block of symbols contains T or less symbol-errors, where T is greater than E.

2. A memory controller as claimed in claim 1, wherein said error detecting circuitry comprises:
partial remainder calculating circuitry responsive to said block of symbols read from said NAND memory to calculate Q partial remainder values resulting from dividing said block of symbols by one of Q factors of a generator polynomial and Q products of factors of a generator polynomial, Q being an integer greater than one and said partial remainder values being indicative of any symbol-errors within said block of symbols.

3. A memory controller as claimed in claim 2, wherein said fast zero-error detecting circuitry is responsive to said partial remainder values all having a zero value to detect that said block of symbols has values corresponding to zero symbol errors.

4. A memory controller as claimed in claim 2, wherein said partial remainder calculating circuitry provides a plurality of parallel computational paths such that partial remainder values calculation can be performed in respect of A symbols per processing cycle.

5. A memory controller as claimed in claim 2, wherein said error correcting circuitry comprises syndrome calculating circuitry responsive to said partial remainder values to calculate S syndrome values.

6. A memory controller as claimed in claim 5, wherein said error correcting circuitry is responsive to said S syndrome values to construct an error locator polynomial having tentative values for each fast computational path having lower values of i, such that i<=M0 and 1<=M0<=M, such that said i^{th} error locator polynomial has a degree i.

7. A memory controller as claimed in claim 6, wherein
at least one of:
a set of said fast computational paths having lower values of i, such that i≦M0 and 1≦M0≦M, allow for the determination if any i symbol-errors occurred during the generation of a further 2T-S syndrome values thereby validating said error locator polynomial;
a set of said fast computational paths having higher values of i, such that M0<i, i≦M and 1≦M0≦M, use iterative computing circuitry responsive to said syndrome values to iteratively compute said error locator polynomial.

8. A memory controller as claimed in claim 6, wherein said slow-path error correcting circuitry uses iterative computing circuitry responsive to said syndrome values to iteratively compute said error locator polynomial.

9. A memory controller as claimed in claim 8, wherein said iterative computing circuitry is shared with a set of said fast computational paths having higher values of i, such that M0<i, i≦M and 1≦M0≦M.

10. A memory controller as claimed in claim 7, wherein if i symbol-errors are detected, then said i^{th} fast computational path is responsive to a degree i error locator polynomial to non-iteratively factor said error locator polynomial into i factors.

11. A memory controller as claimed in claim 10, wherein, if i symbol-errors are detected, then said i^{th} fast computational path uses said i factors to compute in parallel at each cycle a mask value covering B consecutive symbol positions for correcting said i symbol-errors.

12. A memory controller as claimed in claim 11, wherein said error correcting circuitry comprises:
fast-path masking circuitry coupled to said M fast computational paths and responsive to a mask value generated by one of said M fast computational paths to modify said block of symbols so as to correct said i symbol-errors and to generate said stream of corrected symbols at rate of B symbols per cycle.

13. A memory controller as claimed in claim 8, wherein said slow-path error correcting circuitry is responsive to said error locator polynomial to iteratively test for a root of said error locator polynomial for an error case having Y symbol-errors and to use said roots to set in parallel at each cycle a mask value using slow-path mask generating circuitry for correcting in respect of C consecutive symbol positions said Y symbol-errors.

14. A memory controller as claimed in claim 13, wherein said slow-path error correcting circuitry comprises slow-path masking circuitry using said mask values generated by said slow-path error correcting circuit to modify said block of symbols so as to correct said Y symbol-errors and to generate a stream of corrected symbols at rate of C symbols per cycle.

15. A memory controller as claimed in claim 1, wherein said memory controller comprises:
a buffer memory coupled to said NAND memory array to receive a portion of said block of symbols without redundant error correcting symbols, said portion corresponding to data symbols being stored in said memory such that on output using a path through one of said fast zero-error detecting circuitry, said fast-path error correcting circuitry and said slow-path error correcting circuitry said data symbols can be read from said buffer memory.

16. A memory controller as claimed in claim 8, wherein said fast bad-block detecting circuitry is responsive to said iterative computing circuitry being unable to calculate said error locator polynomial to detect that said block of symbols cannot be corrected by said error correcting circuitry thereby guaranteeing fast bad-block detection up when said block of symbols contains T or less symbol-errors.

17. A memory controller as claimed in claim 10 wherein said fast bad block detecting circuitry is responsive to said fast-path error correcting circuitry being unable to calculate said factors to detect that said block of symbols cannot be corrected by said error correcting circuitry thereby guaranteeing fast bad-block detection up when said block of symbols contains T or less symbol-errors.

18. A memory controller as claimed in claim 13, wherein said fast bad-block detecting circuitry is responsive to said fast-path mask generating circuitry being unable to generate masks representing an accumulated error count of exactly i, to detect that said block of symbols cannot be corrected by said error correcting circuitry.

19. A memory controller as claimed in claim 13, wherein said fast bad-block detecting circuitry is responsive to said slow-path mask generating circuitry being unable to generate masks with an accumulated symbol weight of exactly Y, to detect that said block of symbols cannot be corrected by said error correcting circuitry and is a bad-block.

20. A memory controller as claimed in claim 1, wherein said fast zero-error detecting circuitry, said fast-path error correcting circuitry, said slow-path error correcting circuitry and said fast bad-block detecting circuitry process said block of symbols at least partially in parallel.

21. A memory controller as claimed in claim 8, wherein said iterative computing circuitry performs a form of Berlecamp-Massey algorithm to generate said error locator polynomial.

22. A memory controller as claimed in claim 2, wherein said controller is responsive to an error correcting code defined by a generator polynomial comprising a factor g(z)=z−1 and said partial remainder calculating circuitry calculates partial remainders includes the partial remainder of the factor g(z)=z−1, indicating parity of a number of symbol-errors within said block of symbols.

23. A memory controller as claimed in claim 22, wherein said fast zero-error detecting circuitry tests for said parity matching a detected number of symbol-errors.

24. A memory controller as claimed in claim 8, comprising fast parity checking circuitry responsive to a comparison of a degree of said error locator polynomial and a parity symbol of said block of symbols.

25. A memory controller as claimed in claim 24, wherein said error correction circuitry is responsive to a parity check computed by said fast parity checking circuitry to early terminate error correction processing for said block of symbols.

26. A memory controller as claimed in claim 1, wherein said error correction circuitry is responsive to fast bad-block detection by said fast bad block detecting circuitry to early terminate error correction processing for said block of symbols.

27. A memory controller as claimed in claim 5, wherein said syndrome calculating circuitry is configured to perform syndrome value calculation in a single processing cycle.

28. A memory controller as claimed in claim 8, wherein said iterative computing circuitry uses at least one of hardware duplication and hardware pipelining to accelerate processing.

29. A memory controller as claimed in claim 12, wherein said fast-path masking circuitry provides a plurality of parallel computational paths so as to generate said stream of corrected symbols at a rate of B symbols per cycle.

30. A memory controller as claimed in claim 14, wherein said slow-path masking circuitry provides a plurality of parallel computational paths so as to generate said stream of corrected symbols at a rate of C symbols per cycle.

31. A memory controller as claimed in claim 5, wherein said syndrome calculating circuitry multiplies vectors of symbols interpreted as a binary vector with a binary matrix as part of calculating said syndrome values.

32. A memory controller as claimed in claim 31, wherein said binary matrix has elements with values modified to compensate for the effects of data non-alignment of said symbols received by said input circuitry.

33. A memory controller as claimed in claim 31, wherein said binary matrix has elements with values modified to compensate for pipelining delays within said error correction circuitry.

34. A memory controller as claimed in claim 8, wherein said iterative computing circuitry is initialised by a tentative error locator polynomial of a highest degree available.

35. A memory controller as claimed in claim 8, wherein said iterative computing circuitry is initialised by a highest degree error locator polynomial with tenative values.

36. A memory controller for a NAND memory array, said memory controller comprising error detecting means having:
input means for accepting a block of symbols as a stream of symbols at a rate of A symbols per cycle;
fast zero-error detecting means responsive to said block of symbols read from said NAND memory for detecting that said block of symbols has values corresponding to zero symbol errors being present;
fast-path error correcting means for providing M fast computational paths, an i^{th} fast computational path of said M fast computational paths providing correction for any permutation of i symbol-errors within said block of symbols, where M is an integer value greater than zero and less than a maximum number of symbol-errors E to be corrected and i varies within a range 0<i≦M, said fast-path error correcting circuitry generating a stream of corrected symbols at rate of B symbols per cycle;
slow-path error correcting means for providing correction for any permutation of Y symbol-errors within said block of symbol symbols, where Y is an integer value within a range greater than M and less than E, said slow-path error generating a stream of corrected symbols at rate of C symbols per cycle, where C is less than B; and
fast bad-block detecting means for detecting that said block of symbols is a bad-block having greater than E symbol-errors and cannot be corrected by said error correcting circuitry, said fast bad-block detecting circuitry being formed to guarantee bad-block detection up to when said block of symbols contains T or less symbol-errors, where T is greater than E.

37. A method of reading a NAND memory array, said method comprising the steps of:
using input circuitry for accepting a block of symbols as a stream of symbols at a rate of A symbols per cycle;
using fast zero-error detecting circuitry responsive to said block of symbols read from said NAND memory to detect that said block of symbols has values corresponding to zero symbol errors being present;
using fast-path error correcting circuitry providing M fast computational paths, an i^{th} fast computational path of said M fast computational paths providing correction for any permutation of i symbol-errors within said block of symbols, where M is an integer value greater than zero and less than a maximum number of symbol-errors E to be corrected and i varies within a range 0<i≦M, said fast-path error correcting circuitry generating a stream of corrected symbols at rate of B symbols per cycle;
using slow-path error correcting circuitry providing correction for any permutation of Y symbol-errors within said block of symbol symbols, where Y is an integer value within a range greater than M and less than E, said slow-path error generating a stream of corrected symbols at rate of C symbols per cycle, where C is less than B; and
using fast bad-block detecting circuitry adapted to detect that said block of symbols is a bad-block having greater than E symbol-errors and cannot be corrected by said error correcting circuitry, said fast bad-block detecting circuitry being formed to guarantee bad-block detection up to when said block of symbols contains T or less symbol-errors, where T is greater than E.
